(19) United States
(12) Patent Application Publication
(10) Pub. No.: US 2025/0218801 A1
(43) Pub. Date: Jul. 3, 2025

(54) METHOD FOR MANUFACTURING ELECTRONIC COMPONENT OR SEMICONDUCTOR DEVICE

(71) Applicant: LINTEC Corporation, Tokyo (JP)

(72) Inventors: Kanako KONO, Tokyo (JP); Taku NEMOTO, Tokyo (JP); Satoshi KIDA, Tokyo (JP); Kenta NISHIJIMA, Tokyo (JP); Mutsumi MASUMOTO, Beppu-shi (JP)

(21) Appl. No.: 19/085,238

(22) Filed: Mar. 20, 2025

Related U.S. Application Data
(63) Continuation of application No. PCT/JP2023/034243, filed on Sep. 21, 2023.

(30) Foreign Application Priority Data
Sep. 22, 2022 (JP) 2022-151756
Sep. 22, 2022 (JP) 2022-151757

(51) Int. Cl. H01L 21/56; C09J 7/38

(52) U.S. Cl. CPC H01L 21/568; C09J 7/38; H01L 21/561; H01L 21/565

(57) ABSTRACT

Provided is a new method by which it is easier to remove an element after processing, so as to improve productivity in manufacturing an electronic component or a semiconductor device. An object to be processed used in manufacturing an electronic component or a semiconductor device is attached to an uneven surface of a pressure sensitive adhesive layer. The object to be processed on the pressure sensitive adhesive layer is processed to obtain a processed product. The processed product is removed from the pressure sensitive adhesive layer.

### CROSS-REFERENCE TO RELATED APPLICATIONS

This application is a Continuation of International Patent Application No. PCT/JP2023/034243, filed Sep. 21, 2023, which claims the benefit of Japanese Patent Application No. 2022-151756 filed on Sep. 22, 2022 and Japanese Patent Application No. 2022-151757 filed on Sep. 22, 2022, all of which are hereby incorporated by reference herein in their entirety.

### BACKGROUND

### Field

The present disclosure relates to a manufacturing method for an electronic component or a semiconductor device, and for example, relates to a technique for sealing a semiconductor element.

### Description of the Related Art

In manufacturing an electronic component or a semiconductor device, for example, as described in WO 2018/181767, processing including sealing an element or wiring is performed on an object to be processed. As described in WO 2018/181767, the object to be processed is often processed in a state where the object to be processed is attached to a pressure sensitive adhesive sheet.

### SUMMARY

According to an embodiment of the present invention, a manufacturing method for an electronic component or a semiconductor device includes: attaching an object to be processed used for manufacturing an electronic component or a semiconductor device to an uneven surface included in a pressure sensitive adhesive layer; performing processing on the object to be processed on the pressure sensitive adhesive layer to obtain a processed product; and removing the processed product from the pressure sensitive adhesive layer.

Further features of the present invention will become apparent from the following description of exemplary embodiments with reference to the attached drawings.

### BRIEF DESCRIPTION OF THE DRAWINGS

The accompanying drawings, which are incorporated herein and constitute a part of the specification, illustrate embodiments of the present invention, and, together with the description, serve to describe the principles of the present invention.

FIG. 1 is a schematic view of a pressure sensitive adhesive sheet according to one embodiment.

FIG. 2A is a top view illustrating an example of an unevenness of a pressure sensitive adhesive layer.

FIG. 2B is a top view illustrating an example of an unevenness of a pressure sensitive adhesive layer.

FIG. 2C is a top view illustrating an example of an unevenness of a pressure sensitive adhesive layer.

FIG. 3A is a cross-sectional view illustrating an example of an unevenness of a pressure sensitive adhesive layer.

FIG. 3B is a cross-sectional view illustrating an example of an unevenness of a pressure sensitive adhesive layer.

FIG. 3C is a cross-sectional view illustrating an example of an unevenness of a pressure sensitive adhesive layer.

FIG. 4A is a diagram illustrating separation and capture of an element.

FIG. 4B is a diagram illustrating separation and capture of an element.

FIG. 5 is a flowchart of a manufacturing method according to one embodiment.

FIG. 6A is a diagram illustrating a manufacturing method according to one embodiment.

FIG. 6B is a diagram illustrating a manufacturing method according to one embodiment.

FIG. 6C is a diagram illustrating a manufacturing method according to one embodiment.

FIG. 6D is a diagram illustrating a manufacturing method according to one embodiment.

FIG. 7 is a diagram for explaining an apparent contact angle.

### DESCRIPTION OF THE EMBODIMENTS

An embodiment will be described below in detail with reference to the drawings. It should be noted that the following embodiments do not limit the invention according to the appended claims, and all combinations of features described in the embodiments are not necessarily essential to the invention. Any two or more features among a plurality of features described in the embodiments may be combined. The same or similar components are denoted by the same reference numerals, and redundant description is omitted.

After the object to be processed is processed, it is necessary to remove a processed product from the pressure sensitive adhesive sheet. However, it is not easy to remove the processed product from the pressure sensitive adhesive sheet. WO 2018/181767 proposes an addition of thermally expandable particles to a pressure sensitive adhesive in order to easily remove an element to improve productivity.

As a result of intensive studies, the present inventors have found that if processing is performed on an object to be processed after attaching the object to be processed to an uneven surface included in a pressure sensitive adhesive layer, a processed product is easily removed to improve productivity, and thus, it is possible to solve the above-described problems, and have completed the present invention after a great deal of consideration.

Provided is a new method by which a processed product is easily removed so as to improve productivity in manufacturing an electronic component or a semiconductor device.

Other features and advantages of the present invention will become apparent from the following description in conjunction with the accompanying drawings. Note that in the drawings, the same or similar components are denoted by the same reference numerals.

### (Definitions)

As used herein, a mass average molecular weight (Mw) and a number average molecular weight (Mn) are values measured by size exclusion chromatography and calibrated with a polystyrene standard, and more specifically, are values measured based on JIS K7252-1:2016. In addition, in the present specification, “(meth)acrylic” refers to both “acrylic” and “methacrylic”.

As used herein, the “electronic component” includes all components used in electronic engineering, electrical engineering, and the like, and all components included in an electronic device. The “electronic component” may be formed of any one of a semiconductor, a conductor, and/or an insulant, or a combination thereof. Examples of the “electronic components” include an active component (mainly formed of a semiconductor, for example, a transistor, an IC, an LSI, a super LSI, a diode, a light-emitting diode, a thyristor, a three terminal regulator, and an imaging device), a passive element (for example, a resistor, a capacitor, a speaker, a coil, an electric transformer, a transformer, a relay, a piezoelectric element, a quartz oscillator, a ceramic oscillator, and a varistor), and a structural component (for example, a wiring component, a printed circuit board, a connector, and a switch). Also as used herein, a “semiconductor device” refers to any general device that can function by utilizing a semiconductor characteristic and is used for a processor, a memory, a sensor, and the like. Examples of the “semiconductor device” include a micro-light-emitting diode, a mini-light-emitting diode, a power device, micro electro mechanical systems (MEMS), and a controller chip.

As used herein, when one or more lower limit values and one or more upper limit values of a numerical range (for example, a range of a content) are described, it can be understood that a combination of any one of the lower limit values and any one of the upper limit values is described. For example, the description “preferably 1 or greater, more preferably 2 or greater, and even more preferably 3 or greater, and preferably 9 or less, more preferably 8 or less, and even more preferably 7 or less” clearly means that the numerical range may be any of 1 or greater and 9 or less, 1 or greater and 8 or less, 1 or greater and 7 or less, 2 or greater and 9 or less, 2 or greater and 8 or less, 2 or greater and 7 or less, 3 or greater and 9 or less, 3 or greater and 8 or less, and 3 or greater and 7 or less.

In the manufacturing method for an electronic component or a semiconductor device according to one embodiment of the present invention, a pressure sensitive adhesive layer having an uneven surface is used. For example, in such a manufacturing method, processing is performed on an object to be processed attached onto the pressure sensitive adhesive layer. Further, as will be described below, in order to attach the object to be processed to the pressure sensitive adhesive layer, an element separated from a holding substrate may be captured in the pressure sensitive adhesive layer. In the present specification, first, a pressure sensitive adhesive layer having an uneven surface used in the manufacturing method for an electronic component or a semiconductor device will be described.

### (Base Material)

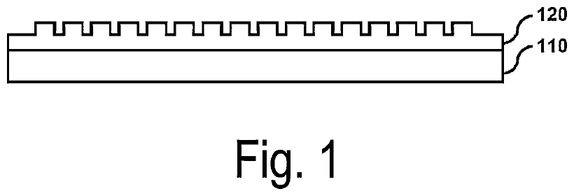

A pressure sensitive adhesive layer may be provided on a base material. For example, as illustrated in FIG. 1, a pressure sensitive adhesive sheet including a base material 110 and a pressure sensitive adhesive layer 120 may be used. In such a case, processing can be performed on an object to be processed attached onto the pressure sensitive adhesive layer 120 of the pressure sensitive adhesive sheet. However, it is not essential that the pressure sensitive adhesive sheet includes the base material 110. For example, the pressure sensitive adhesive sheet may include only the pressure sensitive adhesive layer 120. In such a case, the pressure sensitive adhesive sheet may employ the pressure sensitive adhesive layer 120 having a high supporting property.

The base material 110 functions as a support supporting the pressure sensitive adhesive layer 120. A type of the base material 110 is not particularly limited, and may be a rigid base material or a flexible base material. The base material 110 is preferably a flexible base material from the viewpoint of facilitating attachment of a base material or the like to another member, improving a peeling property, facilitating lamination, or enabling a roll form. An example of the base material 110 includes a resin film.

The resin film is a film in which a resin-based material is used as a main material, and may be formed of a resin material or may contain an additive in addition to the resin material. The resin film may be permeable to laser light.

Specific examples of the resin film include a polyethylene film such as a low-density polyethylene (LDPE) film, a linear low-density polyethylene (LLDPE) film, and a high-density polyethylene (HDPE) film, a polyolefin-based film such as a polypropylene film, a polybutene film, a polybutadiene film, a polymethylpentene film, an ethylene-norbornene copolymer film, and a norbornene resin film; an ethylene-based copolymer film such as an ethylene-vinyl acetate copolymer film, an ethylene-(meth)acrylic acid copolymer film, and an ethylene-(meth)acrylic acid ester copolymer film; a polyvinyl chloride-based film such as a polyvinyl chloride film and a vinyl chloride copolymer film; a polyester-based film such as a polyethylene terephthalate film and a polybutylene terephthalate film; a polyurethane film; a polyimide film; a polystyrene film; a polycarbonate film; and a fluororesin film. In a film containing a mixture of two or more kinds of materials, a cross-linked film in which resins forming such films are cross-linked, and a modified film such as an ionomer film may be used. The base material 110 may be a laminated film in which two or more types of resin films are laminated.

From the viewpoint of versatility, relatively high strength and ease of preventing warpage, and a heat resistance, the resin film is preferably a single-layer film selected from the group consisting of a polyethylene film, a polyester-based film, and a polypropylene film, or a laminated film in which two or more films selected from such a group are laminated.

A thickness of the base material 110 is not particularly limited, but, from the viewpoint of satisfying both a supporting property and a roll winding property, is in a range of preferably from 10 μm to 500 μm, more preferably from 25 μm to 200 μm, and even more preferably from 40 μm to 90 μm.

### (Pressure Sensitive Adhesive Layer)

The pressure sensitive adhesive layer 120 is a layer having pressure sensitive adhesiveness and may include a resin. The surface of the pressure sensitive adhesive layer 120 has an unevenness. Note that the pressure sensitive adhesive sheet may include the pressure sensitive adhesive layer 120 having two or more layers. For example, the pressure sensitive adhesive sheet may have a laminate of one type or two or more types of pressure sensitive adhesive layers 120.

### (Composition of Pressure Sensitive Adhesive Layer)

Examples of resin contained in the pressure sensitive adhesive layer include rubber-based resins such as polyisobutylene-based resins, polybutadiene-based resins, and styrene-butadiene-based resins; acrylic-based resins; urethane-based resins; polyester-based resins; olefin-based resins; silicone-based resins; and polyvinyl ether-based resins. The pressure sensitive adhesive layer may have a heat resistance, and examples of a material of the pressure sensitive adhesive layer having such a heat resistance include a polyimide-based resin and a silicone-based resin. The pressure sensitive adhesive layer may include a copolymer having two or more kinds of constituent units. A form of such a copolymer is not particularly limited, and the copolymer may be any of a block copolymer, a random copolymer, an alternating copolymer, or a graft copolymer.

The resin included in the pressure sensitive adhesive layer 120 is preferably a pressure sensitive adhesive resin having a pressure sensitive adhesiveness on its own. The resin is preferably a polymer having a mass average molecular weight (Mw) of 10,000 or greater. From the viewpoint of improving the adhesion, the mass average molecular weight (Mw) of the resin is preferably 10,000 or greater, more preferably from 70,000 or greater, and even more preferably from 140,000. From a viewpoint of suppressing a storage modulus to a predetermined value or less, the mass average molecular weight (Mw) of the resin is preferably 2,000,000 or less, more preferably 1,200,000 or less, and even more preferably 900,000 or less. From the viewpoint of improving the adhesion, the number average molecular weight (Mw) of the resin is preferably 10,000 or greater, more preferably 50,000 or greater, and even more preferably 100,000 or greater. From the viewpoint of suppressing the storage modulus to a predetermined value or less, the number average molecular weight (Mw) of the resin is preferably 2,000,000 or less, more preferably 1,000,000 or less, and even more preferably 700,000 or less. As will be described later, if the pressure sensitive adhesive layer 120 includes a resin derived from an energy-reactive resin, the mass average molecular weight (Mw) and the number average molecular weight (Mn) refer to the mass average molecular weight (Mw) and the number average molecular weight (Mn) before a cross-linking reaction by energy application. A glass transition temperature (Tg) of the resin is preferably −70° C. or higher, and more preferably −60° C. or higher, and preferably −10° C. or lower, and more preferably −20° C. or lower. When the Tg is within the above range, it is possible to easily maintain the adhesion and the storage modulus of the obtained pressure sensitive adhesive within ranges described later.

An amount of the resin included in the pressure sensitive adhesive layer 120 relative to the total amount of the components included in the pressure sensitive adhesive layer 120 may be appropriately set according to a required adhesion and storage modulus of the pressure sensitive adhesive layer 120, and is preferably 30 mass % or greater, more preferably 40 mass % or greater, even more preferably 50 mass % or greater, still more preferably 55 mass % or greater, and still even more preferably 60 mass % or greater, and preferably 99.99 mass % or less, more preferably 99.95 mass % or less, even more preferably 99.90 mass % or less, still more preferably 99.80 mass % or less, and still even more preferably 99.50 mass % or less.

The resin contained in the pressure sensitive adhesive layer 120 is preferably derived from an energy-reactive resin. The energy-reactive resin refers to a resin having an improved elastic modulus when energy is applied. Examples of the energy-reactive resin include an energy ray-reactive resin and a heat-reactive resin. The energy ray-reactive resin refers to a resin having an improved elastic modulus when the resin is irradiated with energy rays. The heat-reactive resin refers to a resin having an improved elastic modulus when the resin is heated. The type of the energy rays is not particularly limited, and examples thereof include ultraviolet rays, electron beams, and ionizing radiation. The energy rays are preferably ultraviolet rays, that is, the resin is preferably an ultraviolet-reactive resin. The fact that the resin is derived from an energy-reactive resin means that the resin is obtained from an energy-reactive resin. For example, the resin derived from an energy-reactive resin is a cross-linked energy-reactive resin. In the case of using such an energy-reactive resin, when an uneven shape is formed on the resin, and then, energy is applied (for example, the resin is irradiated with energy rays), it is easy to maintain the formed uneven shape.

The pressure sensitive adhesive layer may contain a component other than the resin. For example, the pressure sensitive adhesive layer may include one or more among a tackifier, a polymerization initiator, a UV absorber, and other additives.

The polymerization initiator is a component that initiates a cross-linking reaction in response to application of energy (for example, irradiation with energy rays). In a case where the pressure sensitive adhesive layer contains an energy-reactive resin, if the pressure sensitive adhesive layer further contains a polymerization initiator, the cross-linking reaction proceeds even by application of relatively low energy.

An example of the polymerization initiator may include a photopolymerization initiator. Examples of the photopolymerization initiator include 1-hydroxycyclohexyl phenyl ketone, benzoin, benzoin methyl ether, benzoin ethyl ether, benzoin propyl ether, benzyl phenyl sulfide, tetramethylthiuram monosulfide, azobisisobutyronitrile, dibenzyl, diacetyl, and 8-chloroanthraquinone.

The pressure sensitive adhesive layer may contain one type of polymerization initiator or may contain two or more types of polymerization initiators. When the pressure sensitive adhesive layer contains a polymerization initiator, the content of the polymerization initiator in the pressure sensitive adhesive layer is preferably 0.01 mass % or greater, more preferably 0.1 mass % or greater, and even more preferably 1 mass % or greater, and preferably 10 mass % or less, more preferably 5 mass % or less, and even more preferably 2 mass % or less, such that the cross-linking reaction proceeds at an appropriate rate.

Examples of the UV absorber include a benzotriazole-based compound, an oxazolic acid amide compound, and a benzophenone-based compound.

Other additives that may be contained in the pressure sensitive adhesive layer are not particularly limited, and examples thereof include photostabilizers such as hindered amine-based photostabilizers, benzophenone-based photostabilizers, or benzotriazole-based photostabilizers, phenol-based antioxidants such as hindered phenol-based compounds, aromatic amine-based antioxidants, sulfur-based antioxidants, and phosphorus-based antioxidants such as phosphate-based compounds, resin stabilizers such as imidazole-based resin stabilizers, dithiocarbamate-based resin stabilizers, phosphorus-based resin stabilizers, or sulfur ester-based resin stabilizers, fillers, pigments, extenders, and softners.

When the pressure sensitive adhesive layer contains such additives, the content of the additives in the pressure sensitive adhesive layer is preferably 0.0001 mass % or greater, more preferably 0.01 mass % or greater, particularly preferably 0.1 mass % or greater, and even more preferably 1 mass % or greater, and preferably 20 mass % or less, more preferably 10 mass % or less, and even more preferably 5 mass % or less.

### (Shape of Pressure Sensitive Adhesive Layer)

The surface of the pressure sensitive adhesive layer has an unevenness. As will be described below, after processing is performed on the object to be processed attached onto the pressure sensitive adhesive layer, the object to be processed is removed from the pressure sensitive adhesive layer. If the surface of the pressure sensitive adhesive layer is flat, the pressure sensitive adhesive layer and the object to be processed closely contact each other. At this time, even if an attempt is made to remove the object to be processed from the pressure sensitive adhesive layer, air does not easily enter between the pressure sensitive adhesive layer and the object to be processed, and thus, a sufficiently large force is required to remove the object to be processed from the pressure sensitive adhesive layer. On the other hand, there is a gap between the pressure sensitive adhesive layer having an uneven surface and the object to be processed, and thus, the object to be processed is easily removed from the pressure sensitive adhesive layer.

As will be described below, the pressure sensitive adhesive sheet can capture, in the pressure sensitive adhesive layer, the object to be processed separated from the holding substrate in order to attach the object to be processed onto the pressure sensitive adhesive layer. Specifically, the pressure sensitive adhesive layer can capture the object to be processed at a convex portion of the pressure sensitive adhesive layer. At this time, gas compressed between the object to be processed and the pressure sensitive adhesive layer when the object to be processed and the pressure sensitive adhesive layer closely contact each other can escape to a concave portion of the pressure sensitive adhesive layer. As described above, the pressure sensitive adhesive layer has an unevenness, and thus, a pressure generated between the object to be processed and the pressure sensitive adhesive layer can be relaxed. Therefore, it is also possible to suppress a displacement of a holding position of the object to be processed on the pressure sensitive adhesive layer due to the pressure generated between the object to be processed and the pressure sensitive adhesive layer.

As described above, when the surface of the pressure sensitive adhesive layer has the concave portion, the force required for removing the object to be processed from the pressure sensitive adhesive layer can be adjusted by controlling the contact area between the object to be processed and the pressure sensitive adhesive layer. If the surface of the pressure sensitive adhesive layer includes the concave portion, the pressure generated between the object to be processed and the pressure sensitive adhesive layer can be relaxed. Therefore, a specific shape of the unevenness of the surface of the pressure sensitive adhesive layer is not limited.

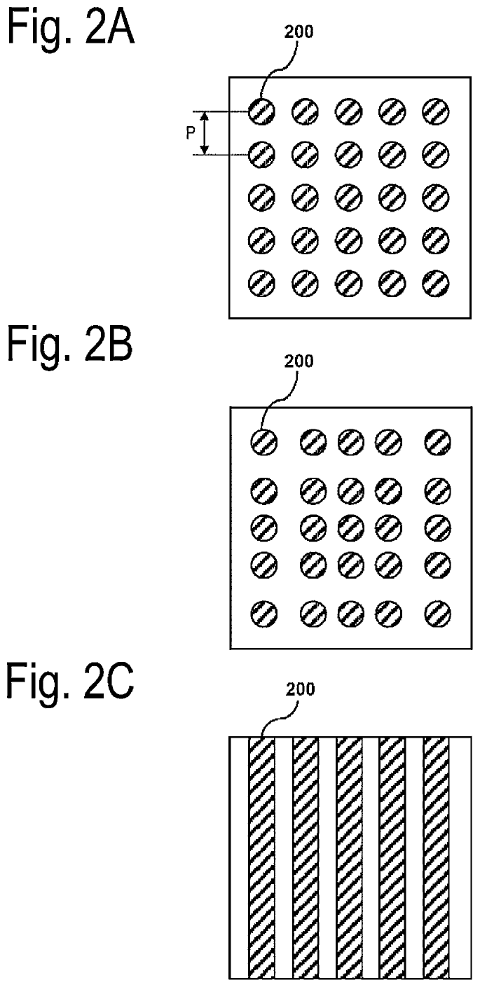

For example, in one embodiment, the pressure sensitive adhesive layer includes, on a surface thereof, a plurality of convex portions separated from each other via a concave portion. Each of the plurality of convex portions may be separated by the concave portion continuing over the entire pressure sensitive adhesive layer. If such a continuous concave portion is provided around the convex portion, air can more easily enter between the pressure sensitive adhesive layer and the object to be processed, and thus, the object to be processed can be more easily removed from the pressure sensitive adhesive layer. In one embodiment, the concave portion positioned in the periphery of each of the plurality of convex portions is continuous to an end portion of the pressure sensitive adhesive layer. As described above, if the concave portion continuous to the end portion of the pressure sensitive adhesive layer is provided, air is more likely to enter between the object to be processed and the pressure sensitive adhesive layer. According to such configurations, the air compressed between the object to be processed and the convex portion can be efficiently released to the outside of the object to be processed, and thus, an effect of relaxing pressure is further increased. FIGS. 2A to 2C are top views illustrating the shape of such a pressure sensitive adhesive layer.

As illustrated in FIG. 2A, the convex portions may be regularly arranged on the surface of the pressure sensitive adhesive layer. The regular arrangement of the convex portions refers to an arrangement in which the convex portions are arranged at regular intervals on a straight line. As illustrated in FIG. 2B, the convex portions may be arranged so that the intervals thereof vary regularly. In the example illustrated in FIG. 2B, the intervals between the convex portions are short in a central portion of the pressure sensitive adhesive layer, and the intervals between the convex portions are long in a peripheral portion of the pressure sensitive adhesive layer. According to such a configuration, while the holding power of the pressure sensitive adhesive layer is increased, air easily enters between the pressure sensitive adhesive layer and the object to be processed from the peripheral portion of the object to be processed via the wide concave portion, and the pressure can be efficiently released from the peripheral portion of the object to be processed. Furthermore, the convex portions may be arranged irregularly.

FIG. 2C is a top view illustrating another shape of the pressure sensitive adhesive layer. As illustrated in FIG. 2C, stripe-shaped convex portions may be provided on the surface of the pressure sensitive adhesive layer. In FIG. 2C, line-shaped convex portions having constant widths are arranged at constant intervals. On the other hand, similarly to FIG. 2B, the widths or the intervals of the line-shaped convex portions may vary regularly, or the line-shaped convex portions may be arranged irregularly.

A pitch of the convex portions is preferably 1 μm or greater, more preferably 5 μm or greater, even more preferably 10 μm or greater, and still more preferably 15 μm or greater, in order to easily remove the object to be processed or to enhance an effect of relaxing pressure. Here, the pitch of the convex portions refers to a minimum interval among all intervals of the convex portions in the entire pressure sensitive adhesive layer. For example, in the case of FIG. 2A, the pitch of the convex portions represents an interval between the convex portions on a straight line on which the convex portions are arranged at constant intervals. When the convex portions are arranged on a plurality of straight lines, the pitch represents an interval between convex portions on a straight line on which the convex portions are arranged at the shortest intervals. In the case of FIG. 2C, the pitch of the convex portions represents an interval between the line-shaped convex portions. In the present specification, the interval between the convex portions refers to an interval between centers of the convex portions.

On the other hand, if the pitch of the convex portions is narrowed, it is possible to increase the contact area between the pressure sensitive adhesive layer and the object to be processed to suppress the positional deviation in capturing the object to be processed. Furthermore, as will be described below, in one embodiment, the object to be processed on the pressure sensitive adhesive is sealed with a sealing material. At this time, the surface of the pressure sensitive adhesive layer has a finer structure, and thus, the wettability of the sealing material before curing with respect to the surface of the pressure sensitive adhesive layer is reduced, and the sealing material is less likely to enter into the unevenness. Such a phenomenon that the wettability is lowered on the surface having the fine structure is generally called a lotus effect. For example, lotus leaves are known to exhibit high water repellency if the lotus leaves have a fine structure with a pitch of 20 to 30 μm and a height of about 10 μm on the surface. One of the reasons for such a decrease in wettability is that when a fluid comes into contact with the surface of the pressure sensitive adhesive layer, an air chamber is formed in a concave portion of the surface. From such viewpoints, the pitch of the convex portions is preferably 100 μm or less, more preferably 75 μm or less, even more preferably 50 μm or less, still more preferably 35 μm or less, and still even more preferably 25 μm or less.

As illustrated in FIG. 2B, the shortest interval among all the intervals between the convex portions in the central portion of the pressure sensitive adhesive layer may be shorter than the shortest interval among all the intervals between the convex portions in the peripheral portion of the pressure sensitive adhesive layer. For example, the central portion is a circular region including ¼ of the area of the pressure sensitive adhesive layer and being centered on the center of gravity of the pressure sensitive adhesive layer. The peripheral portion of the pressure sensitive adhesive layer includes, for example, the entire region other than the central portion of the pressure sensitive adhesive layer.

A specific shape of each of the convex portions is not particularly limited. For example, the convex portion may have a pillar (column) shape. In a specific example, the convex portion may have a cylindrical shape or a prismatic shape. The convex portion may extend in a line shape as described above, or may extend in a curved shape such as a wave shape. Furthermore, each of the convex portions may be tapered.

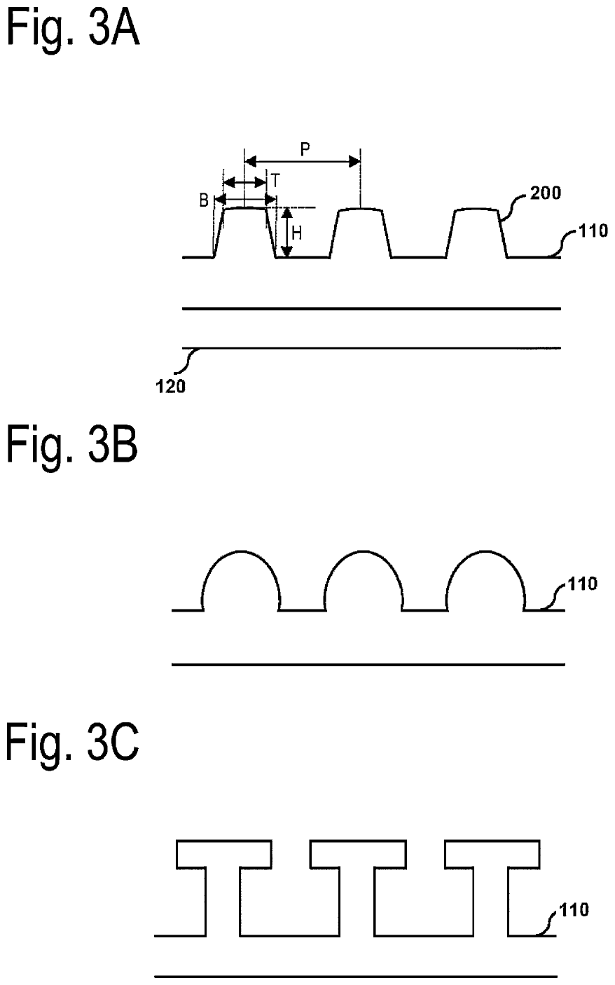

FIG. 3A illustrates a cross-sectional view of the pressure sensitive adhesive layer according to one embodiment, and the cross-sectional view is cut through the convex portions and is perpendicular to the surface of the pressure sensitive adhesive layer. The convex portions illustrated in FIG. 3A are tapered, that is, the convex portions decrease in width toward the top. As illustrated in FIG. 3A, a top of each of the convex portions may be a curved surface. According to such a configuration, the impact generated when an object to be processed separated from the holding substrate and the pressure sensitive adhesive layer contact each other is further relaxed. Therefore, the pressure sensitive adhesive layer can easily hold the object to be processed without the object to be processed being displaced. The top of the convex portion may be a flat surface.

As illustrated in FIG. 3A, the surface of the pressure sensitive adhesive layer may have a flat concave portion and convex portions protruding from the concave portion. As described above, the plurality of convex portions that are included in the pressure sensitive adhesive layer and are separated from each other may be separated with a boundary defined by the concave portion.

In another example, each of the convex portions may have a hemispherical shape or may be a part of a sphere, as illustrated in FIG. 3B. The convex portion may have a T-shape, as illustrated in FIG. 3C. In still another example, the convex portion may have a shape in which a plurality of grains are gathered, a mushroom shape, a lotus leaf surface shape, or a needle shape. In still another example, the surface of the pressure sensitive adhesive layer may be a rough surface or may be in the shape of fibers, and such a surface also has an unevenness.

The width or the diameter of each of the convex portions is preferably 1 μm or greater, more preferably 2 μm or greater, even more preferably 5 μm or greater, and still more preferably 10 μm or greater, in order to maintain the adhesion. On the other hand, the width or the diameter of each of the convex portions is preferably 100 μm or less, more preferably 50 μm or less, even more preferably 30 μm or less, and still more preferably 20 μm or less, in order to easily remove the object to be processed or to enhance the effect of relaxing pressure. Here, the width and the diameter of the convex portions respectively refer to the shortest distance and the longest distance (indicated by B in FIG. 3A) between two parallel lines contacting from both sides of the convex portions on the surface of the concave portion.

The area of each of the convex portions is preferably 10 μm² or greater, more preferably 20 μm² or greater, and even more preferably 30 μm² or greater, in order to maintain the adhesion. On the other hand, the area of each of the convex portions is preferably 2000 μm² or less, more preferably 1000 μm² or less, and even more preferably 500 μm² or less, in order to easily remove the object to be processed or to enhance the effect of relaxing pressure. Here, the area of the convex portion refers to an area of a portion protruding from the surface of the concave portion (an area of a circle having a diameter B in the case of FIG. 3A).

The height of each of the convex portions is preferably 1 μm or greater, more preferably 3 μm or greater, and even more preferably 5 μm or greater, in order for air to easily enter into the concave portion. On the other hand, the height of each of the convex portions is preferably 20 μm or less, more preferably 15 μm or less, and even more preferably 10 μm or less, in order to enhance the morphological stability. Here, the height of the convex portion is represented by H in FIG. 3A.

An area occupied by the plurality of convex portions relative to the area of the pressure sensitive adhesive layer is preferably 1% or greater, more preferably 5% or greater, even more preferably 10% or greater, still more preferably 18% or greater, and still even more preferably 40% or greater, in order to maintain the adhesion. On the other hand, the area of each of the convex portions is preferably 95% or less, more preferably 75% or less, and even more preferably 60% or less, in order to enhance the effect of relaxing pressure.

The unevenness of the pressure sensitive adhesive layer may be designed in accordance with the shape of the object to be processed. For example, a ratio of the adhesion area between the pressure sensitive adhesive layer and one object to be processed relative to the area of the one object to be processed is preferably 1% or greater, more preferably 2% or greater, even more preferably 3% or greater, still more preferably 4% or greater, still even more preferably 5% or greater, further more preferably 7% or greater, and even further more preferably 10% or greater, in order to maintain the adhesion. On the other hand, the area of each of the convex portions is preferably 95% or less, more preferably 70% or less, even more preferably 50% or less, and still more preferably 30% or less, in order to easily remove the object to be processed or to enhance the effect of relaxing pressure. In the case of FIG. 3A, the adhesion area corresponds to the area of a circle having a diameter T. If a position of the object to be processed deviates on the pressure sensitive adhesive layer, the adhesion area may change. In such a case, it is preferable that the ratio of the adhesion areas is within the above-mentioned range, regardless of the position of the object to be processed.

### (Other Layers)

The pressure sensitive adhesive sheet may include a layer other than the base material 110 and the pressure sensitive adhesive layer 120. For example, an additional pressure sensitive adhesive layer may be provided on the surface of the base material 110 on the opposite side of the pressure sensitive adhesive layer 120. The pressure sensitive adhesive sheet may attach to another substrate such as quartz glass via such a pressure sensitive adhesive layer. The type of the additional pressure sensitive adhesive layer is not particularly limited, and for example, the additional pressure sensitive adhesive layer can be formed by using a general pressure sensitive adhesive.

### (Manufacturing Method for Pressure Sensitive Adhesive Layer and Pressure Sensitive Adhesive Sheet)

A manufacturing method for a pressure sensitive adhesive layer and a pressure sensitive adhesive sheet is not particularly limited. For example, a pressure sensitive adhesive sheet including the pressure sensitive adhesive layer 120 on the base material 110 can be prepared as described below. First, an organic solvent is added to a raw material composition containing each component of the pressure sensitive adhesive layer described above, to prepare a solution of the raw material composition. The solution can be applied onto a base material to form a coating film, and then the coating film is dried to provide the pressure sensitive adhesive layer on the base material 110. Furthermore, processing can be performed to provide an unevenness on the surface of the pressure sensitive adhesive layer, and thus, the pressure sensitive adhesive layer 120 having an unevenness can be formed.

Examples of the organic solvent used for preparing the solution of the raw material composition include toluene, ethyl acetate, and methyl ethyl ketone. The solid content concentration of the solution of the raw material composition is preferably 10 mass % or greater, more preferably 25 mass % or greater, and even more preferably 45 mass % or greater, and is preferably 80 mass % or less, more preferably 70 mass % or less, and even more preferably 65 mass % or less. Examples of a coating method of the solution include a spin coating method, a spray coating method, a bar coating method, a knife coating method, a roll coating method, a roll knife coating method, a blade coating method, a die coating method, a gravure coating method, and a printing method (for example, a screen printing method and an ink jet method).

The processing for providing an unevenness on the surface of the pressure sensitive adhesive layer is also not particularly limited. For example, an imprint method can be used to provide an unevenness on the surface of the pressure sensitive adhesive layer. In the imprint method, it is possible to use a mold having a surface of which the shape is complementary to the unevenness to be provided. Specifically, the unevenness can be provided on the surface of the pressure sensitive adhesive layer by heating the pressure sensitive adhesive layer provided on the base material while pressing the pressure sensitive adhesive layer with a mold. A more specific example of the method includes a method in which the pressure sensitive adhesive layer is pressed with a mold, and the pressure sensitive adhesive layer is heated and maintained in the heated state for a predetermined time. Subsequently, the pressure sensitive adhesive layer is cooled, and the mold can be removed. When the pressure sensitive adhesive layer is heated, for example, the pressure sensitive adhesive layer can be heated to a temperature higher than the softening point of the pressure sensitive adhesive layer. The time during which the pressure sensitive adhesive layer is maintained in the heated state is not particularly limited. For example, the pressure sensitive adhesive layer may be maintained in the heated state during 10 seconds or more, or during 10 minutes or less. A specific example of a method for heating the pressure sensitive adhesive layer while pressing the pressure sensitive adhesive layer with the mold, includes a method for vacuum laminating the mold and the pressure sensitive adhesive layer provided on the base material. Instead of performing a two-step process of forming the pressure sensitive adhesive layer and forming the unevenness, the pressure sensitive adhesive layer 120 having an unevenness on the surface may be formed on the base material 110 in a one-step process.

In another method, the pressure sensitive adhesive layer having a rough surface can be provided by applying a solution of the raw material composition as a spray. Furthermore, the pressure sensitive adhesive layer having a rough surface or a surface in the shape of fibers can be provided by adding a filler to the solution of the raw material composition and applying the obtained solution. In still another method, a solution of the raw material composition is applied according to a desired pattern by using a printing method such as an ink jet method, and thus, it is possible to directly provide the pressure sensitive adhesive layer having an uneven shape on the base material.

A pressure sensitive adhesive sheet in which the base material 110 is not provided can be manufactured by forming a sheet of a composition containing each component of the pressure sensitive adhesive layer. Furthermore, a liquid pressure sensitive adhesive containing each component of the pressure sensitive adhesive layer may be applied onto any object to form the pressure sensitive adhesive layer. In such a cases, after the pressure sensitive adhesive layer is formed, the surface of the pressure sensitive adhesive layer may be subjected to processing for providing an unevenness. Alternatively, the pressure sensitive adhesive layer may be formed by a method for forming an unevenness on a surface.

### (Manufacturing Method for Electronic Component or Semiconductor Device Using Pressure Sensitive Adhesive Layer)

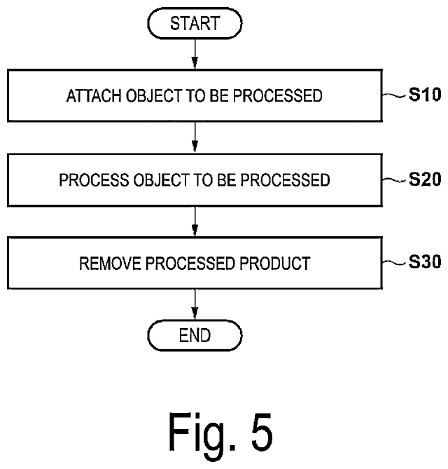

A manufacturing method for such an electronic component or a semiconductor device employing the pressure sensitive adhesive layer as described above will be described below in detail with reference to the flowchart of FIG. 5.

### (S10: Attach Object to be Processed)

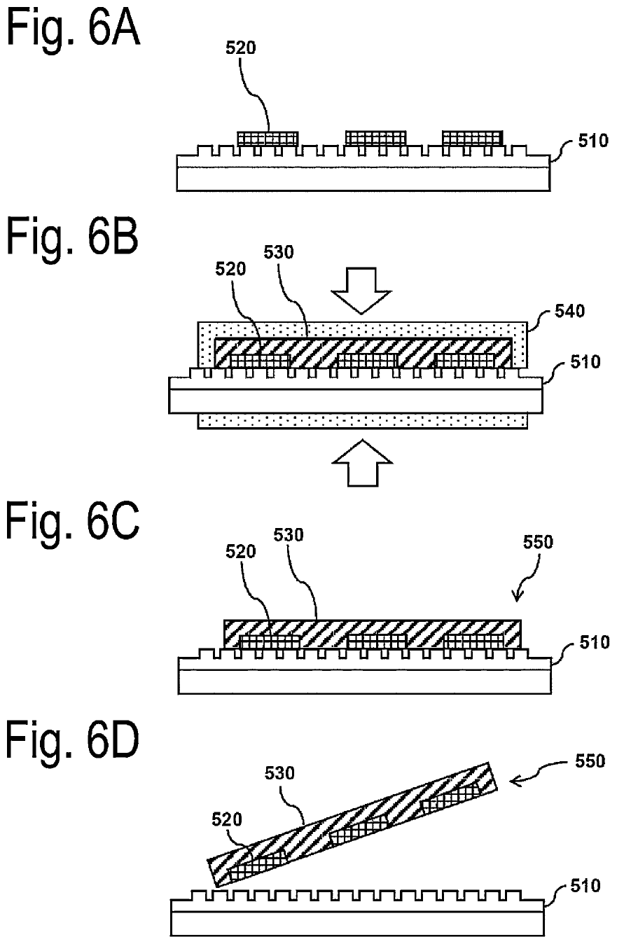

In step S10, an object to be processed used in manufacturing an electronic component or a semiconductor device is attached to an uneven surface included in a pressure sensitive adhesive layer. For example, as illustrated in FIG. 6A, an object to be processed 520 can be attached to the surface of the pressure sensitive adhesive sheet 510. There is no particular limitation on the method of attaching the object to be processed. For example, an object to be processed can be placed on the pressure sensitive adhesive layer by using an apparatus such as a flip chip bonder or a die bonder. The arrangement layout, the number of arrangements, and the like of the objects to be processed can be appropriately determined according to a form of a sealed body to be produced, the number of products, and the like.

The type of the object to be processed is not particularly limited. The object to be processed may be, for example, an element, a wafer, a panel, or a substrate. For example, the element may be a semiconductor chip such as an LED chip, a semiconductor chip having a protective film, a semiconductor chip having a die attach film (DAF), or the like. Furthermore, the element may be a micro light-emitting diode, a mini light-emitting diode, a power device, micro electro mechanical systems (MEMS), or a controller chip, or may be a constituent component of these devices. The element may be a singulated product such as a wafer, a panel, and a substrate. The element may include a circuit surface on which an integrated circuit including circuit elements such as transistors, resistors, and capacitors is formed.

The size of the element is not particularly limited. For example, the size of the element may be 100 μm² or greater, 500 μm² or greater, or 1000 μm² or greater. On the other hand, the size of the element may be 100 mm² or less, 25 mm² or less, or 1 mm² or less. When an element having a small size is used, a laser lift-off method described later is suitable for attaching the element, because it is easy to selectively separate the small element.

The object to be processed is not necessarily limited to a singulated product. For example, the object to be processed may be various types of wafers, various types of panels, various types of substrates, or the like, which are not singulated.

Examples of the wafer include semiconductor wafers such as a silicon wafer, a silicon carbide (SiC) wafer, and a compound semiconductor wafer (for example, a gallium phosphide (GaP) wafer, a gallium arsenide (GaAs) wafer, an indium phosphide (InP) wafer, and a gallium nitride (GaN) wafer). The size of the wafer is not particularly limited, but may be 8 inches (200 mm in diameter) or greater and is preferably 12 inches (300 mm in diameter) or greater. A shape of the wafer is not limited to a circular shape and may be, for example, an angular shape such as a square and a rectangle.

Examples of the panel include a fan-out type semiconductor package (for example, a fan-out wafer-level package (FOWLP) or a fan-out panel-level package (FOPLP)). That is, the object to be processed may be a semiconductor package before singulation or after singulation in a fan-out type semiconductor package manufacturing technique. The size of the panel is not particularly limited, and the panel may be an angular substrate of about 300 to 700 mm, for example.

Examples of the substrate include a glass substrate, a sapphire substrate, and a compound semiconductor substrate.

Hereinafter, a case where an element is used as an object to be processed will be mainly described. However, the method described below may also be applied to a case where another object to be processed is used.

In the case of using a pressure sensitive adhesive layer having an unevenness on the surface, it is preferable to transfer the element from the holding substrate to the pressure sensitive adhesive layer by a method including a step of separating the element from the holding substrate and a step of capturing the element in the pressure sensitive adhesive layer. Thus, the element can be attached to the uneven surface of the pressure sensitive adhesive layer. Such a method will be described below.

### (S10-1: Prepare Holding Substrate)

First, a holding substrate attached with an element is prepared. The type of the holding substrate is not particularly limited. For example, the holding substrate may be a pressure sensitive adhesive sheet or a tray. The pressure sensitive adhesive sheet may include a pressure sensitive adhesive layer, and the pressure sensitive adhesive layer may be provided on a base material. In this case, the holding substrate can hold the element in the pressure sensitive adhesive layer. The base material may be a resin film or a rigid base material.

A method for preparing such a holding substrate that holds the element is not particularly limited. For example, the semiconductor wafer can be attached to the holding substrate, and further, the semiconductor wafer can be diced. Thus, an element can be obtained by dicing the semiconductor wafer, so that it is possible to obtain a holding substrate to which the element is attached.

In another method, an element obtained by dicing a semiconductor wafer is transferred to a holding substrate, and thus, it is possible to obtain a holding substrate to which the element is attached. For example, after the semiconductor wafer held on the wafer substrate is diced, the obtained element can be brought into close contact with the pressure sensitive adhesive layer of the holding substrate. Subsequently, by applying an external stimulus such as laser light, the adhesiveness between the wafer substrate and the element can be lowered. Through such a process, the element can be transferred from the wafer substrate to the holding substrate.

As will be described below, the element can be separated from the holding substrate by irradiation with laser light (laser lift-off method). When such a method is used, it is preferable that the pressure sensitive adhesive layer of the holding substrate contain a laser light absorber. Examples of the laser light absorber include one or more types selected from pigments and dyes.

### (S10-2: Separate Element)

Next, the element attached to the holding substrate is separated from the holding substrate by an external stimulus. The type of the external stimulus is not particularly limited, and examples thereof include application of energy, cooling, drawing of the holding substrate, and physical stimulation (for example, pressing of a rear surface of the holding substrate by using a pin or the like). With one or more of these external stimuli, the bonding force between the holding substrate and the element can be reduced and the element can be separated from the holding substrate.

As will be described below, the elements can be captured after the element is separated such that the relative arrangement of the plurality of elements on the holding substrate is different from the relative arrangement of the plurality of elements on the pressure sensitive adhesive layer. Thus, it is preferable to selectively separate some of the plurality of elements attached to the holding substrate. Accordingly, it is possible to selectively apply an external stimulus to some of the plurality of elements attached to the holding substrate or to an attachment site of the elements on the holding substrate.

Examples of a method for applying energy include local heating, light irradiation, and heat ray irradiation. Examples of the light irradiation method include infrared irradiation, visible light irradiation, and laser light irradiation. Preferably, laser light irradiation is used as the external stimulus, that is, the element is separated from the holding substrate by a laser lift-off method. In this case, laser light is emitted toward an attachment site of a specific element on the holding substrate. For example, the laser light may be emitted from a side opposite to the side of the holding substrate where the element is located. At a contact portion between the specific element and the holding substrate, gas is generated. For example, when the laser light is absorbed by the pressure sensitive adhesive layer, gas is generated by sublimation of at least a part of the pressure sensitive adhesive layer. When at least a part of the pressure sensitive adhesive layer sublimates as described above, the adhesion area between the specific element and the pressure sensitive adhesive layer decreases, and thus, the adhesive strength between the specific element and the holding substrate is reduced. Furthermore, the pressure of the generated gas also reduces the adhesive strength between the specific element and the holding substrate. As a result, the specific element is separated from the holding substrate.

The irradiation conditions of the laser light are not particularly limited. In order to selectively and efficiently separate a part of the elements, the frequency of the laser light is preferably from 10,000 Hz to 100,000 Hz. Further, the beam diameter of the laser light is preferably 10 μm or greater, and more preferably 20 μm or greater. On the other hand, the beam diameter is preferably 100 μm or less, and more preferably 40 μm or less. The output of the laser light is preferably from 0.1 W to 10 W. The scanning speed of the laser light is preferably from 50 mm/second to 2000 mm/second.

### (S10-3: Capture Element)

The element separated from the holding substrate is captured in the pressure sensitive adhesive layer. Specifically, the element is removed relative to the holding substrate. Further, the element relatively approaches the pressure sensitive adhesive layer. When the element and the pressure sensitive adhesive layer of the pressure sensitive adhesive sheet contact each other, the element is captured in the pressure sensitive adhesive layer.

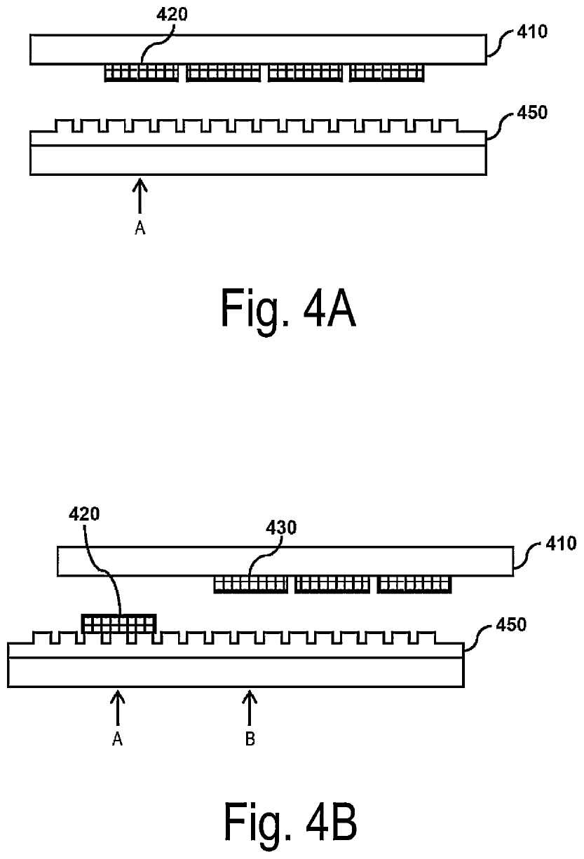

As illustrated in FIG. 4A, by positioning a position A on a pressure sensitive adhesive sheet 450 so as to face an element 420 adhering to a holding substrate 410, the separated element 420 is captured at the position A on the pressure sensitive adhesive sheet 450. Furthermore, as illustrated in FIG. 4B, by positioning a position B on the pressure sensitive adhesive sheet 450 so as to face an element 430 adhering to the holding substrate 410, the separated element 430 is captured at the position B on the pressure sensitive adhesive sheet 450. Thus, it is possible to separate and capture the element, while changing the relative position between the holding substrate and the pressure sensitive adhesive layer in a plane direction. Therefore, the elements can be positioned such that the relative arrangement of the plurality of elements on the holding substrate is different from the relative arrangement of the plurality of elements on the pressure sensitive adhesive layer. As described above, when a pressure sensitive adhesive layer having a flat surface is used, the element 420 may be captured at a position deviated from the position A in the example of FIG. 4A due to pressure generated between the element and the pressure sensitive adhesive layer. However, when the surface of the pressure sensitive adhesive layer has an unevenness, the pressure generated between the element and the pressure sensitive adhesive layer is relaxed, such that it is easier to capture the element at a desired position of the pressure sensitive adhesive layer.

In one embodiment, the holding substrate and the pressure sensitive adhesive layer are stationary, and the element separated from the holding substrate moves to the pressure sensitive adhesive layer. For example, when a laser lift-off method is used, the element can move toward the pressure sensitive adhesive layer by the pressure of the gas generated by the irradiation with laser light. However, the element does not necessarily need to move. For example, the holding substrate may move away from the element. Alternatively, the pressure sensitive adhesive layer may move so as to approach the element.

### (S20: Process Object to be Processed)

In step S20, processing is performed on the object to be processed on the pressure sensitive adhesive layer. The processing method is not particularly limited. Examples of the processing include wiring formation, back metal formation, cleaning, plating processing, singulation, and thinning. The processing on the object to be processed may include energy application processing (for example, heating or irradiation with an energy ray such as light), liquid contact processing (for example, etching), under-vacuum processing (for example, vacuum deposition or sputtering), or sealing processing. Through such processing, a processed product can be obtained. Hereinafter, in an example, a case of sealing an element will be described.

In one embodiment, a sealed body is formed by sealing the element on the pressure sensitive adhesive layer with a sealing material. First, the element attached onto the pressure sensitive adhesive layer is covered with a sealing material. Specifically, as illustrated in FIG. 6B, the element 520 can be covered with a sealing material 530 such that the exposed surfaces of the element 520, for example, a surface and a side surface of the element 520 opposite to a pressure sensitive adhesive sheet 510 are covered. On the other hand, when the element 520 is covered with the sealing material 530, the surface of the element 520 on a side of the pressure sensitive adhesive sheet 510 may not be covered. At this time, two or more elements 520 may be integrally covered with the sealing material 530. In the example of FIG. 6B, two or more elements 520 that are disposed separately on the uneven surfaces are integrally sealed. In such a case, a gap between the two or more elements 520 is filled with the sealing material 530. After the element attached onto the pressure sensitive adhesive layer is covered with the sealing material, the sealing material is cured. If the sealing material 530 is cured, a sealed body 550 including the element 520 is formed as illustrated in FIG. 6C. According to such a method, the sealed body 550 can be formed such that the sealing material is in contact with both the element and the uneven surface of the pressure sensitive adhesive layer.

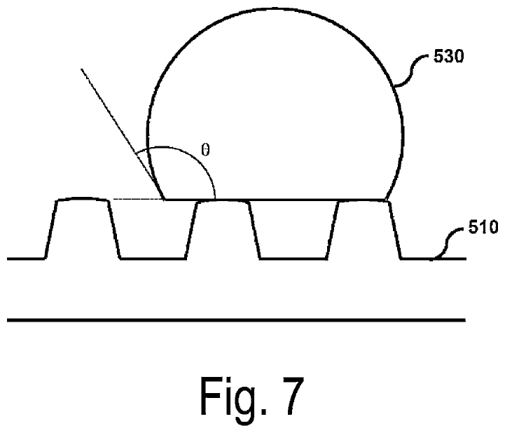

As described above, due to the lotus effect, a fluid hardly enters the fine structure of the uneven surface of the pressure sensitive adhesive layer. Therefore, the sealed body 550 can be formed such that the concave portion on the surface of the pressure sensitive adhesive sheet 510 is not filled with the sealing material 530 and air enters the concave portion. From the viewpoint of making it difficult for the sealing material 530 to enter into the unevenness of the pressure sensitive adhesive layer, the apparent contact angle between the uneven surface of the pressure sensitive adhesive layer and the sealing material before curing (the contact angle when the uneven surface is regarded as a flat surface, and represented by θ in FIG. 7) is preferably more than 90°, more preferably more than 100°, and still more preferably more than 110°. From a similar viewpoint, when a flat pressure sensitive adhesive layer is formed, the contact angle between such a layer and the sealing material before curing is preferably greater than 90°, and more preferably greater than 100°, and the pressure sensitive adhesive is preferably selected such that the contact angle is greater than 110°. Preferably, an apparent contact angle between the uneven surface of the pressure sensitive adhesive layer and the sealing material before curing is larger than a contact angle between a flat layer of the pressure sensitive adhesive and the sealing material before curing.

The sealing material has the function of protecting the element and components associated with the element from the external environment. The type of the sealing material is not particularly limited. The sealing material has curability from the viewpoint of mechanical strength, heat resistance, insulating properties, and the like.

Examples of the sealing material include a thermosetting resin composition and an energy ray-curable resin composition. Examples of the thermosetting resin contained in the thermosetting resin composition include an epoxy resin, a phenol resin, and a cyanate resin. From the viewpoint of mechanical strength, heat resistance, insulating properties, moldability, and the like, the thermosetting resin is preferably an epoxy resin. The thermosetting resin composition may contain, in addition to the thermosetting resin, a curing agent such as a phenol resin-based curing agent or an amine-based curing agent, a curing accelerator, an inorganic filler such as silica, or an additive such as an elastomer, if necessary. The sealing material may be solid or liquid at room temperature. The form of the sealing material that is solid at room temperature is not particularly limited, and may be, for example, a granular form or a sheet form.

The method of covering the element with the sealing material is not particularly limited, and for example, a roll lamination method, a vacuum press method, a vacuum lamination method, a spin coating method, a die coating method, a transfer molding method, a compression molding method, or the like can be applied. In such methods, in order to increase the filling property of the sealing material, the sealing material can be heated in covering the element to impart fluidity.

A method for sealing the element preferably uses compression molding. In the compression molding, a sealing material is filled in a cavity having a desired shape and pressed to obtain a sealed body having a desired shape. For example, in the example illustrated in FIG. 6B, a cavity in a mold 540 is filled with the sealing material 530. The forming pressure at this time is, for example, 0.1 MPa or greater, preferably 0.2 MPa or greater, more preferably 0.3 MPa or greater, and for example, 2.0 MPa or less, preferably 1.8 MPa or less, and more preferably 1.6 MPa or less. The compression molding may be performed while reducing the pressure in the cavity. When the compression molding is performed, the sealing material can be cured during pressurization.

When a thermosetting resin composition is used as the sealing material, the sealing material can be cured by heating the sealing material. The heating temperature at this time can be selected according to the type of the sealing material, and is, for example, 30° C. or greater, preferably 50° C. or greater, and more preferably 70° C. or greater, and for example, 180° C. or less, preferably 170° C. or less, and more preferably 150° C. or less. The heating time is, for example, 5 seconds or greater, preferably 10 seconds or greater, and more preferably 15 seconds or greater, and for example, 60 minutes or less, preferably 45 minutes or less, and more preferably 30 minutes or less.

As described above, two or more objects to be processed that are disposed separately on the uneven surface can be integrally sealed. Two or more objects to be processed are integrally sealed, and then may be further singulated. For example, an aggregate of packages each including two or more objects to be processed is manufactured by integrally sealing the two or more objects to be processed, and then the aggregate is singulated, whereby a plurality of packages each including an object to be processed can be manufactured.

The thus obtained sealed body can be subjected to further processing. For example, a rewiring layer can be formed on the surface of the sealed body. That is, the manufacturing method for an electronic component or a semiconductor device according to the present embodiment can be used in a fan-out process such as FOWLP or FOPLP. For example, a region having a size larger than the element size can be covered with the sealing material, and the rewiring layer and an external electrode can be formed not only on the circuit surface of the element but also on the surface of the sealing material.

The above-described processing for an object to be processed can be used in combination. For example, after two or more objects to be processed are integrally sealed and a rewiring layer is formed on the surface of the sealing material, the obtained structure may be singulated.

### (S30: Remove Processed Product)

In step S30, a processed product obtained by the processing on the object to be processed is removed from the pressure sensitive adhesive layer. When the element is sealed in step S20, the sealed body 550 is removed from the pressure sensitive adhesive sheet 510 as illustrated in FIG. 6D. As described above, air is contained in the concave portions on the surface of the pressure sensitive adhesive sheet 510, and thus, the sealed body 550 is attached to the pressure sensitive adhesive sheet 510, but the sealed body 550 has a portion not in close contact with the pressure sensitive adhesive sheet 510. Therefore, the sealed body 550 can be easily removed from the pressure sensitive adhesive sheet 510 as compared with the case where the unevenness is not formed on the pressure sensitive adhesive layer.

When the surface of the sealed body to which the pressure sensitive adhesive layer has been attached is subjected to further processing, a reinforcing member may be attached to the surface of the sealed body opposite to the surface to which the pressure sensitive adhesive layer is attached, if necessary, in order to improve handleability of the sealed body. The reinforcing member is not particularly limited, and for example, a reinforcing plate excellent in heat resistance such as a glass epoxy resin can be used. Such a reinforcing plate can be attached to the entire surface of the sealed body. The reinforcing member can be attached via an adhesive line, for example. The reinforcing member is removed after further processing, and thus, it is preferable to select an adhesive line that allows the reinforcing member to be peeled off. Such attachment of the reinforcing member can be performed by, for example, laminating a thermosetting adhesive line and a reinforcing plate in this order on the sealed body. Further, if necessary, both the reinforcing plate side and the pressure sensitive adhesive layer side may be sandwiched between plate-like members and pressed under predetermined temperature, time, and pressure conditions. An example of the plate-like members in such a case includes a metal plate made of stainless steel or the like.

The invention is not limited to the above-described embodiments, and various modifications and changes can be made within the spirit of the invention.

What is claimed is:

1. A manufacturing method for an electronic component or a semiconductor device comprising:
attaching an object to be processed used for manufacturing an electronic component or a semiconductor device to an uneven surface included in a pressure sensitive adhesive layer;
performing processing on the object to be processed on the pressure sensitive adhesive layer to obtain a processed product; and
removing the processed product from the pressure sensitive adhesive layer.

2. The manufacturing method according to claim 1, wherein the object to be processed is an element, a semiconductor wafer, or a panel.

3. The manufacturing method according to claim 1, wherein the processing on the object to be processed includes energy application processing, liquid contact processing, under-vacuum processing, or sealing processing.

4. The manufacturing method according to claim 1, wherein in the performing processing, a sealed body is formed by sealing the object to be processed on the pressure sensitive adhesive layer with a sealing material, and in the removing, the sealed body including the object to be processed is removed from the pressure sensitive adhesive layer.

5. The manufacturing method according to claim 4, wherein in the performing processing, the sealed body is formed such that the sealing material is in contact with both the object to be processed and an uneven surface included in the pressure sensitive adhesive layer.

6. The manufacturing method according to claim 4, wherein in the performing processing, two or more objects to be processed that are disposed separately on the uneven surface are integrally sealed.

7. The manufacturing method according to claim 6, wherein in the performing processing, the two or more objects to be processed are integrally sealed and then further singulated.

8. The manufacturing method according to claim 1, wherein the attaching the object to be processed includes capturing an object to be processed separated from a holding substrate in the pressure sensitive adhesive layer.

9. The manufacturing method according to claim 1, wherein the pressure sensitive adhesive layer includes a base material and a pressure sensitive adhesive layer being formed on the base material and having a surface including an unevenness.

10. The manufacturing method according to claim 1, wherein the pressure sensitive adhesive layer includes, on the surface, a plurality of convex portions separated from each other via a concave portion.

11. The manufacturing method according to claim 1, wherein the pressure sensitive adhesive layer includes a convex portion with a boundary defined by a concave portion, and
a ratio of an area occupied by the convex portion relative to an area of the pressure sensitive adhesive layer is 1% or greater and 95% or less.

12. The manufacturing method according to claim 1, wherein the pressure sensitive adhesive layer is configured such that a ratio of an adhesion area between the pressure sensitive adhesive layer and one object to be processed relative to an area of the one object to be processed is 1% or greater and 95% or less.

13. The manufacturing method according to claim 1, wherein an area of the object to be processed is 100 mm² or less.
